(19) United States
(12) Patent Application Publication
(10) Pub. No.: US 2023/0217681 A1
(43) Pub. Date: Jul. 6, 2023

(54) DISPLAY DEVICE

(71) Applicant: LG Display Co., Ltd., Seoul (KR)

(72) Inventors: KyuNam KIM, Paju-si (KR); SeungHan LEE, Paju-si (KR); Tae-Kyung KIM, Paju-si (KR); SeongYong UHM, Paju-si (KR); Dohyung KIM, Paju-si (KR); MinHo OH, Paju-si (KR)

(21) Appl. No.: 17/963,825

(22) Filed: Oct. 11, 2022

(30) Foreign Application Priority Data
Dec. 31, 2021 (KR) 10-2021-0194598

(51) Int. Cl. H01L 51/52; H01L 51/00; G03F 7/029

(52) U.S. Cl. CPC H01L 51/5237; H01L 51/0085; H01L 51/0087; H01L 51/0081; G03F 7/029

(57) ABSTRACT

A display device includes a sacrificial layer positioned between an encapsulation layer and a light-emitting element that includes a first compound that is the same as a first compound of a light-emitting layer of the light-emitting element, thereby protecting the light-emitting element from an outgas of the encapsulation layer to prevent the generation of dark spots.

### CROSS REFERENCE TO RELATED APPLICATION

This application claims priority from Republic of Korea Patent Application No. 10-2021-0194598, filed on Dec. 31, 2021, which is hereby incorporated by reference for all purposes as if fully set forth herein.

### BACKGROUND

### 1. Field

Embodiments of the present disclosure relate to a display device.

### 2. Description of the Related Art

A display device may include various light-emitting elements to display information. Among the various light-emitting elements, an organic light-emitting element is a light-emitting element using an organic light-emitting phenomenon. An organic light-emitting element includes a layer including an organic material between an anode and a cathode in order to use the organic light-emitting phenomenon.

Since the organic light-emitting element uses an organic material vulnerable to external oxygen and moisture, it is necessary to protect the organic light-emitting element from external oxygen and moisture. In order to protect the organic light-emitting element from external oxygen and moisture, there is a need to encapsulate the organic light-emitting element.

### SUMMARY

An encapsulation layer may be formed on a light-emitting element to encapsulate the light-emitting element. The encapsulation layer may include a plurality of layers and may include an organic layer and an inorganic layer. However, the organic layer included in the encapsulation layer may generate an outgas during a curing process of the encapsulation layer, and there is a problem in that the outgas generated in the encapsulation layer penetrates into an organic layer of a light-emitting device to generate dark spots. Accordingly, the inventors of the present disclosure have invented a display device capable of preventing dark spots from being generated in a light-emitting element due to an outgas generated in an encapsulation layer.

An aspect of the present disclosure is to provide a display device which includes a light-emitting layer including a first compound and an encapsulation layer and includes a sacrificial layer positioned between the light-emitting layer and the encapsulation layer and including the first compound, thereby preventing the generation of dark spots due to an outgas of the encapsulation layer.

In an aspect, embodiments of the present disclosure provide a display device including a substrate, a light-emitting element positioned on the substrate, a sacrificial layer disposed on the light-emitting element, and an encapsulation layer positioned on the sacrificial layer.

The light-emitting element may include a light-emitting layer including a first compound.

The sacrificial layer may include the first compound.

The encapsulation layer may include a second compound.

According to embodiments of the present disclosure, there can be provided a display device in which a sacrificial layer positioned between an encapsulation layer and a light-emitting element includes a first compound that is the same as a first compound of a light-emitting layer of the light-emitting element, thereby protecting the light-emitting element from an outgas of the encapsulation layer to prevent the generation of dark spots.

### BRIEF DESCRIPTION OF THE DRAWINGS

The above and other aspects, features and advantages of the present disclosure will be more apparent from the following detailed description taken in conjunction with the accompanying drawings.

FIG. 1 is a system configuration diagram of a display device according to embodiments of the present disclosure.

FIG. 2 is a configuration diagram of a display area of a display device according to embodiments of the present disclosure.

FIG. 3 is a cross-sectional view of a portion of a display area of a display device according to embodiments of the present disclosure.

FIG. 4 is a plan view of a portion of a display area of a display device according to embodiments of the present disclosure.

FIG. 5 is a cross-sectional view of a portion of a display area of a display device according to embodiments of the present disclosure.

FIG. 6 is a plan view of a portion of a display area of a display device according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise stated, the term “alkyl” or “alkyl group” used in the present disclosure may have 1 to 60 carbon atoms that are single-bonded and may be a saturated aliphatic functional radical including a straight chain alkyl group, a branched chain alkyl group, a cycloalkyl (alicyclic) group, an alkyl-substituted cycloalkyl group, or a cycloalkyl-substituted alkyl group.

The term “haloalkyl group” or “halogen alkyl group” used in the present disclosure may be a halogen-substituted alkyl group.

The term “alkoxy group” or “alkyloxy group” used in the present disclosure is an alkyl group having an oxygen radical attached thereto. Unless otherwise stated, the “alkoxy group” or “alkyloxy group” may have 1 to 60 carbon atoms.

Unless otherwise stated, the term “aryl group” and “arylene group” used in the present disclosure have 6 to 60 carbon atoms, but the present disclosure is not limited thereto. In the present disclosure, the aryl group or the arylene group may include a monocyclic compound, a ring assembly, fused polycyclic systems, a spiro compound, or the like. For example, the aryl group may include a phenyl group, biphenyl, naphthyl, anthryl, indenyl, phenanthryl, triphenylenyl, pyrenyl, peryleneyl, chrysenyl, naphthacenyl, fluoranthenyl, and the like, but the present disclosure is not limited thereto. The naphthyl may include 1-naphthyl and 2-naphthyl, and the anthryl may include 1-anthryl, 2-anthryl, or 9-anthryl.

Hereinafter, various embodiments of the present disclosure will be described in detail with reference to the accompanying drawings.

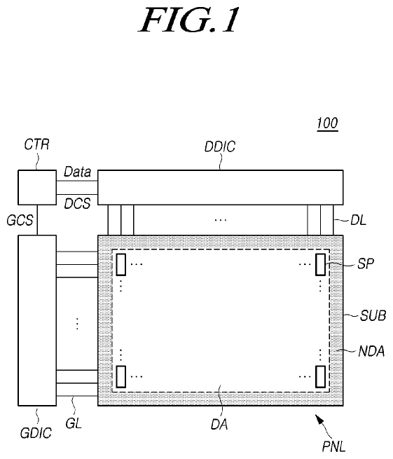

FIG. 1 is a system configuration diagram of a display device 100 according to embodiments of the present disclosure.

Referring to FIG. 1, the display device 100 according to embodiments of the present disclosure may include a display panel PNL and a driving circuit for driving the display panel PNL.

The driving circuit may include a data driving circuit DDIC and a gate driving circuit GDIC and may further include a controller CTR for controlling the data driving circuit DDIC and the gate driving circuit GDIC.

The display panel PNL may include a substrate SUB and signal lines such as a plurality of data lines DL and a plurality of gate lines GL disposed on the substrate SUB. The display panel PNL may include a plurality of subpixels SP connected to the plurality of data lines DL and the plurality of gate lines GL.

The display panel PNL may include a display area DA in which an image is displayed and a non-display area NDA in which an image is not displayed. In the display panel PNL, the plurality of subpixels SP for displaying an image may be disposed in the display area DA, and in the non-display area NDA, the driving circuits DDIC and GDIC, and the controller CTR may be electrically connected or mounted, and a pad portion to which an integrated circuit or a printed circuit is connected may also be disposed.

The data driving circuit DDIC may be a circuit for driving the plurality of data lines DL and may supply data signals to the plurality of data lines DL. The gate driving circuit GDIC may be a circuit for driving the plurality of gate lines GL and may supply gate signals to the plurality of gate lines GL. The controller CTR may supply a data control signal DCS to the data driving circuit DDIC to control an operation timing of the data driving circuit DDIC. The controller CTR may supply a gate control signal GCS to the gate driving circuit GDIC to control an operation timing of the gate driving circuit GDIC.

The controller CTR may start a scan according to a timing implemented in each frame. The controller CTR may convert input image data input from an external device to be suitable for a data signal format used by the data driving circuit DDIC, may supply the converted image data to the data driving circuit DDIC, and may control data driving at an appropriate time according to the scan.

In order to control the gate driving circuit GDIC, the controller CTR may output various gate control signals GCS including gate start pulse (GSP), gate shift clock (GSC), and gate output enable (GOE) signals.

In order to control the data driving circuit DDIC, the controller CTR may output various data control signals DCS including source start pulse (SSP), source sampling clock (SSC), and source output enable (SOE) signals.

The controller CTR may be implemented as a separate component from the data driving circuit DDIC or may be integrated with the data driving circuit DDIC and implemented as an integrated circuit.

The data driving circuit DDIC receives image data DATA from the controller CTR and supplies data voltages to the plurality of data lines DL to drive the plurality of data lines DL. Here, the data driving circuit DDIC is also referred to as a source driving circuit.

The data driving circuit DDIC may include one or more source driver integrated circuits (SDICs).

For example, each SDIC may be connected to the display panel PNL as a tape automated bonding (TAB) type, may be connected to a bonding pad of the display panel PNL as a chip-on-glass (COG) or chip-on-panel (COP) type, or may be implemented as a chip-on-film (COF) type and connected to the display panel PNL.

The gate driving circuit GDIC may output a gate signal having a turn-on level voltage or a gate signal having a turn-off level voltage under the control of the controller CTR. The gate driving circuit GDIC may sequentially drive the plurality of gate lines GL by sequentially supplying a gate signal having a turn-on level voltage to the plurality of gate lines GL.

The gate driving circuit GDIC may be connected to the display panel PNL as a TAB type, may be connected to a bonding pad of the display panel PNL as a COG or COP type, or may be connected to the display panel PNL as a COF type. Alternatively, the gate driving circuit GDIC may be formed in the non-display area NDA of the display panel PNL as a gate-in-panel (GIP) type. The gate driving circuit GDIC may be disposed on or connected to the substrate SUB. That is, when the gate driving circuit GDIC is the GIP type, the gate driving circuit GDIC may be disposed in the non-display area NDA of the substrate SUB. When the gate driving circuit GDIC is the COG type, the COF type, or the like, the gate driving circuit GDIC may be connected to the substrate SUB.

Meanwhile, at least one driving circuit of the data driving circuit DDIC and the gate driving circuit GDIC may be disposed in the display area DA. For example, at least one driving circuit of at least one of the data driving circuit DDIC and the gate driving circuit GDIC may be disposed to not overlap the subpixels SP or may be disposed such that a portion or the entirety thereof overlaps the subpixels SP.

When a specific gate line GL is opened by the gate driving circuit GDIC, the data driving circuit DDIC may convert the image data DATA received from the controller CTR into an analog data voltage and may supply the analog data voltage to the plurality of data lines DL.

The data driving circuit DDIC may be connected to one side (for example, an upper or lower side) of the display panel PNL. According to a driving method, a panel design method, or the like, the data driving circuit DDIC may be connected to two sides (for example, the upper and lower sides) of the display panel PNL or may be connected to two or more sides of the four sides of the display panel PNL.

The gate driving circuit GDIC may be connected to one side (for example, a left side or a right side) of the display panel PNL. According to a driving method, a panel design method, or the like, the gate driving circuit GDIC may be connected to two sides (for example, the left and right sides) of the display panel PNL or may be connected to two or more sides of the four sides of the display panel PNL.

The controller CTR may be a timing controller used in typical display technology, may be a control device, which may include the timing controller, to further perform other control functions, may be a control device different from the timing controller, or may be a circuit inside a control device. The controller CTR may be implemented with various circuits or electronic components such as an IC, a field programmable gate array (FPGA), an application specific integrated circuit (ASIC), and a processor.

The controller CTR may be mounted on a printed circuit board, a flexible printed circuit, or the like and may be electrically connected to the data driving circuit DDIC and the gate driving circuit GDIC through the printed circuit board or the flexible printed circuit.

The display device 100 according to the present embodiments may be a display including a backlight unit such as a liquid crystal display or may be a self-luminous display such as an organic light-emitting diode (OLED) display, a quantum dot display, or a micro light-emitting diode (micro LED) display.

When the display device 100 according to the present embodiments is the OLED display, each subpixel SP may include an OLED, which emits light by itself, as a light-emitting element. When the display device 100 according to the present embodiments is the quantum dot display, each subpixel SP may include a light-emitting element made of quantum dots which are a semiconductor crystal that emits light by itself. When the display device 100 according to the present embodiments is the micro LED display, each subpixel SP may include a micro LED, which emits light by itself and is made based on an inorganic material, as a light-emitting element.

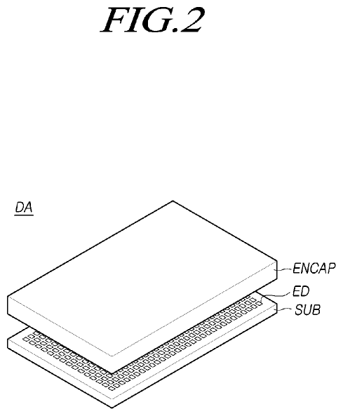

FIG. 2 is a configuration diagram of a display area of a display device according to embodiments of the present disclosure.

Referring to FIG. 2, the display device may include a substrate SUB, a light-emitting element ED disposed on the substrate SUB, and an encapsulation layer ENCAP disposed on the light-emitting element ED.

In a display area DA, a plurality of light-emitting elements ED may be positioned on the substrate SUB. One or more light-emitting elements ED may be positioned in each subpixel disposed on the substrate SUB.

In a display area DA, the encapsulation layer ENCAP may be positioned on the light-emitting element ED. Since the light-emitting element ED is vulnerable to external moisture or oxygen, the encapsulation layer ENCAP may be positioned on the light-emitting element ED to prevent the external moisture or oxygen from penetrating into the light-emitting element ED. The encapsulation layer ENCAP may be disposed in a form which covers the light-emitting elements ED.

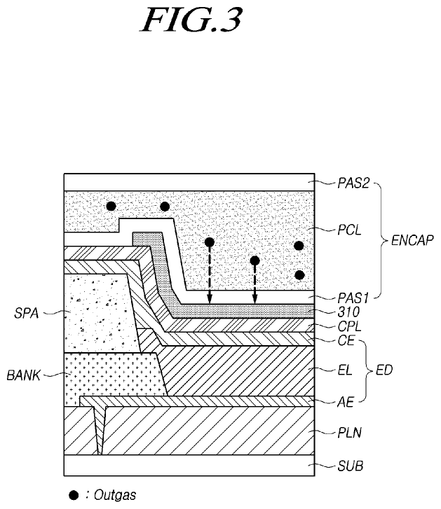

FIG. 3 is a cross-sectional view of a portion of a display area of a display device according to embodiments of the present disclosure.

Referring to FIG. 3, the display device may include a substrate SUB, a light-emitting element ED disposed on the substrate SUB, a sacrificial layer 310 positioned on the light-emitting element ED, and an encapsulation layer ENCAP disposed on the sacrificial layer 310.

Various circuit elements such as a transistor may be positioned on the substrate SUB. A planarization layer PLN for planarizing the circuit elements may be positioned on the substrate SUB. An anode AE may be positioned on the planarization layer PLN. A bank BANK and a light-emitting layer EL may be positioned on the anode AE. A spacer SPA may be positioned on the bank BANK. A cathode CE may be positioned on the spacer SPA and the light-emitting layer EL. A capping layer CPL may be positioned on the cathode CE. The sacrificial layer 310 may be positioned on the capping layer CPL. A first inorganic layer PAS1 may be positioned on the sacrificial layer 310. An organic layer PCL may be positioned on the first inorganic layer PAS1. A second inorganic layer PAS2 may be positioned on the organic layer PCL.

The anode AE may be electrically connected to the transistor (not shown) positioned on the substrate SUB. The bank BANK positioned on the anode AE may define an emission area of the light-emitting element ED.

The light-emitting layer EL may be a layer in which holes moving from the anode AE and electrons moving from the cathode CE meet to emit light and may include, for example, a host compound and a dopant compound.

The capping layer CPL may be a layer for increasing the efficiency of light emitted from the light-emitting layer EL through a micro-cavity effect and may be a layer having a thickness in consideration of a micro-cavity.

The light-emitting element ED may include the light-emitting layer EL including a first compound. The first compound may be the dopant compound of the light-emitting layer EL.

A type of the first compound is not particularly limited as long as the first compound may be used as a dopant of the light-emitting layer EL of the light-emitting element ED.

The first compound may be, for example, one of the following compounds.

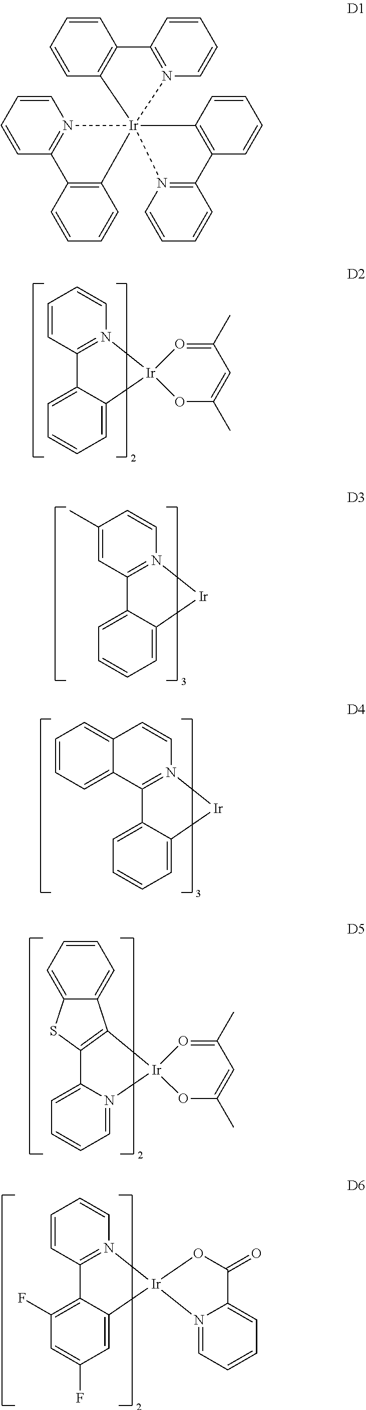

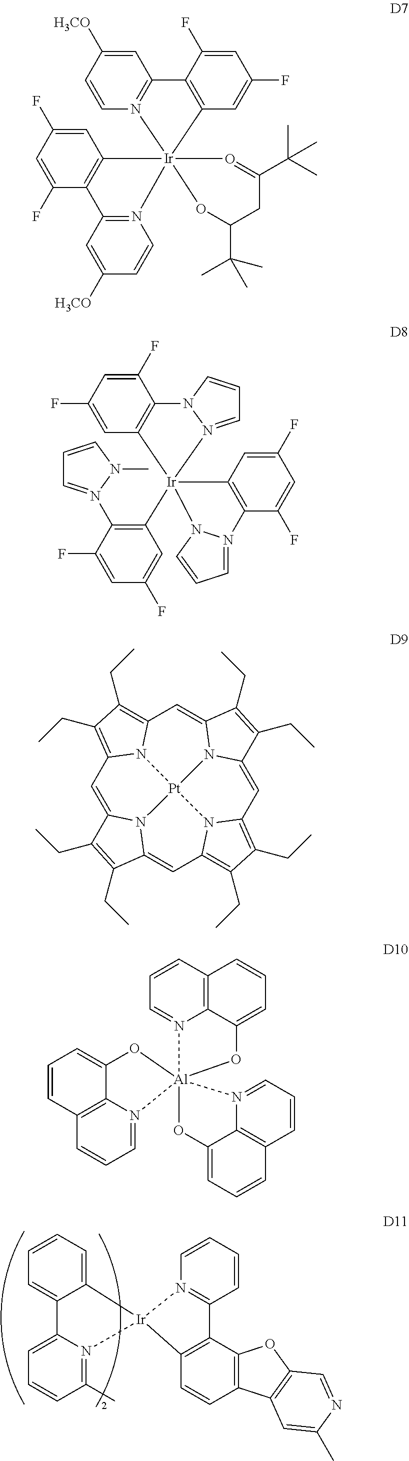

The sacrificial layer 310 may include a first compound. The first compound of the sacrificial layer 310 is the same compound as the first compound of the light-emitting layer EL. When the sacrificial layer 310 includes the first compound that is the same as the first compound of the light-emitting layer EL, it is possible to prevent an outgas, which is generated from the organic layer PCL constituting the encapsulation layer ENCAP, from reacting with the dopant compound of the light-emitting layer EL to generate dark spots.

The first compound of the sacrificial layer 310 may be the dopant compound of the light-emitting layer EL. When the sacrificial layer 310 includes the first compound that is the dopant compound of the light-emitting layer EL, it is possible to prevent an outgas, which is generated from the organic layer PCL constituting the encapsulation layer ENCAP, from reacting with the dopant compound of the light-emitting layer EL to generate dark spots.

In order to effectively prevent the generation of the dark spots, a thickness of the sacrificial layer may be 5 to 200 μm, preferably 10 to 100 μm, and more preferably 20 to 50 μm.

In addition, the first compound may have a concentration of 10 mol % or more, preferably 50 mol % or more, and more preferably 80 mol % or more in the sacrificial layer. When the concentration of the first compound satisfies the above range, it is possible to sufficiently prevent an outgas, which is generated from the organic layer PCL constituting the encapsulation layer ENCAP, from reacting with the dopant compound of the light-emitting layer EL to generate dark spots.

The encapsulation layer ENCAP may be a layer positioned on the light-emitting element ED and may include a plurality of layers PAS1, PCL, and PAS2. For example, the encapsulation layer ENCAP may include the organic layer PCL and inorganic layers PAS1 and PAS2.

The inorganic layers PAS1 and PAS2 may be formed through deposition.

The organic layer PCL may include a photocurable resin and a photoinitiator. The organic layer PCL may be formed through a photocuring process of the photocurable resin and the photoinitiator. However, a radical derived from the photoinitiator may be generated through the photocuring process. A second compound included in the encapsulation layer ENCAP may be a radical derived from such a photoinitiator. The radical may act as an outgas to penetrate into the light-emitting layer EL of the light-emitting element ED and cause dark spots. In order to prevent the generation of dark spots due to an outgas, the sacrificial layer 310 is positioned in a path through which an outgas generated from the encapsulation layer ENCAP penetrates into the light-emitting layer EL, and the first compound of the light-emitting layer EL vulnerable to the outgas generated from the encapsulation layer ENCAP is included in the sacrificial layer 310, thereby preventing the first compound of the light-emitting layer EL from being deteriorated by the outgas.

The photoinitiator may include, for example, one of the following compounds.

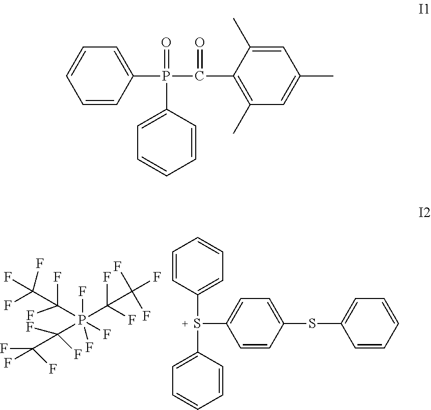

In order for the sacrificial layer 310 to effectively prevent dark spots from being generated in the light-emitting layer EL, the sacrificial layer 310 may be positioned in an entire area in which the light-emitting layer EL is positioned. When the sacrificial layer 310 is positioned as described above, it is possible to effectively block an outgas generated from the organic layer PCL constituting the encapsulation layer ENCAP from penetrating into the light-emitting layer EL.

An area in which the light-emitting layer EL is positioned may be substantially the same as an area in which the sacrificial layer 310 is positioned. When the area in which the light-emitting layer EL is positioned is the same as the area in which the sacrificial layer 310 is positioned, since the two layers can be formed using the same mask, a manufacturing process is efficient.

The sacrificial layer 310 may include a third compound. The third compound may be a reaction product of the first compound and the second compound. For example, the first compound may be the same compound as the dopant compound of the light-emitting layer EL, the second compound may be a radical derived from a photoinitiator included in the organic layer PCL constituting the encapsulation layer ENCAP, and the third compound may be a compound in which the second compound, which is a radical, combines with the first compound at a specific position thereof.

The third compound may be represented by Formula 1 and Formula 2 below.

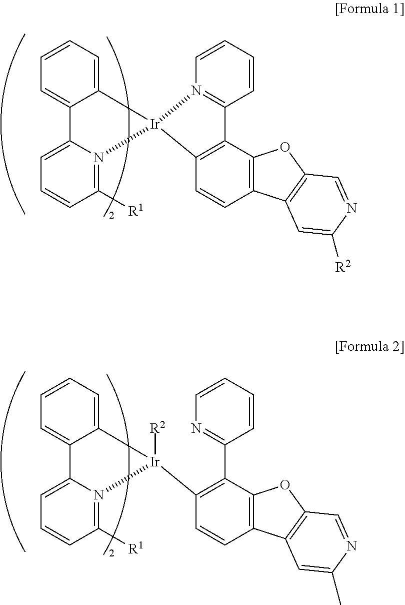

In Formula 1 and Formula 2, R¹ and R² may be each independently selected from the group consisting of hydrogen, deuterium, halogen, a C₁-C₂₀ alkyl group, a C₁-C₂₀ haloalkyl group, a C₁-C₂₀ alkoxy group, a C₆-C₂₀ aryl group, —C(═O)R³, —P(═O)(R⁴)(R⁵), and —S(R⁶)(R⁷). However, at least one of R¹ and R² is not hydrogen and deuterium.

R³ to R⁷ are each independently a C₆-C₂₅ aryl group.

The aryl groups may be each independently substituted with a C₁-C₁₀ alkyl group and S(R⁸), wherein R⁸ is a C₆-C₂₀ aryl group.

For example, R¹ and R² may each independently be

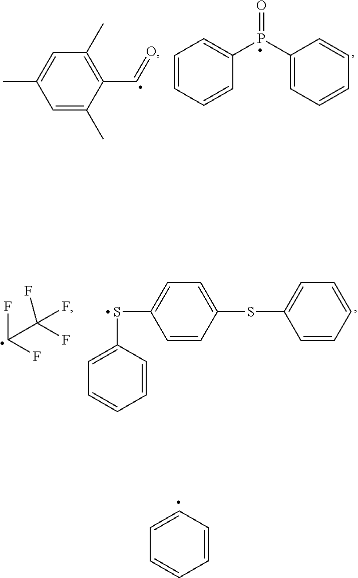

### or F⁻.

A difference in molecular weight between the third compound and the first compound may be in a range of 19 to 294. Since the third compound is the reaction product of the first compound and the second compound, and the second compound is the radical derived from the photoinitiator, the difference in molecular weight between the third compound and the first compound is closely related to a molecular weight of the radical derived from the photoinitiator.

For example, when the photoinitiator included in the organic layer PCL of the encapsulation layer ENCAP is I1, radicals that may be derived from I1 may be

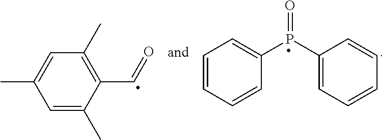

Since a molecular weight of

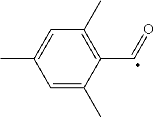

is 147 and a molecular weight of

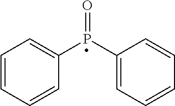

is 201, in such an example, a difference in molecular weight between the third compound and the first compound may be 147 or 201. In such an example, when nuclear magnetic resonance (NMR) spectroscopy measurement is performed on samples taken from the light-emitting layer EL, the sacrificial layer 310, and the encapsulation layer ENCAP, some of the peaks of the sample of the sacrificial layer 310 may be measured to have a molecular weight in which a value obtained by multiplying 147 by an integer of 1 or more is added to any one of the peaks of the sample of the light-emitting layer EL or have a molecular weight in which a value obtained by multiplying 201 by an integer of 1 or more is added to any one of the peaks of the sample of the light-emitting layer EL.

In another example, when the photoinitiator included in the organic layer PCL of the encapsulation layer ENCAP is I2, a radical that may be derived from I2 may be

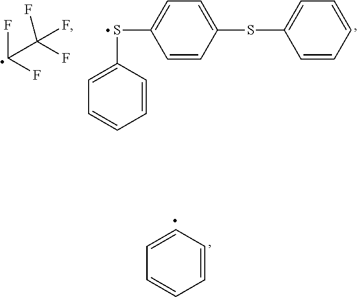

or F⁻. Since a molecular weight of

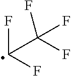

is 119, a molecular weight of

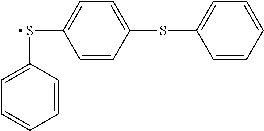 [SMILES: c1ccc(Sc2ccc(Sc3ccccc3)cc2)cc1]

is 294, a molecular weight of

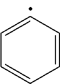

is 77, and an F⁻ molecular weight is 19, in such an example, a difference in molecular weight between the third compound and the first compound may be 147 or 201. In such an example, when NMR spectroscopy measurement is performed on samples taken from the light-emitting layer EL, the sacrificial layer 310, and the encapsulation layer ENCAP, some of the peaks of the sample of the sacrificial layer 310 may be measured to have a molecular weight in which a value obtained by multiplying 119 by an integer of 1 or more is added to any one of the peaks of the sample of the light-emitting layer EL, have a molecular weight in which a value obtained by multiplying 294 by an integer of 1 or more is added to any one of the peaks of the sample of the light-emitting layer EL, have a molecular weight in which a value obtained by multiplying 77 by an integer of 1 or more is added to any one of the peaks of the sample of the light-emitting layer EL, or have a molecular weight in which a value obtained by multiplying 19 by an integer of 1 or more is added to any one of the peaks of the sample of the light-emitting layer EL.

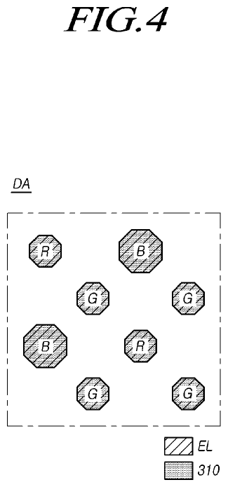

FIG. 4 is a plan view of a portion of a display area of a display device according to embodiments of the present disclosure.

Referring to FIG. 4, a display area DA may include areas R, G, and B in which a light-emitting layer is positioned. In addition, a sacrificial layer 310 may also disposed to overlap the light-emitting layer in the areas in which the light-emitting layer is positioned. Accordingly, since the sacrificial layer 310 is positioned in the entire area in which the light-emitting layer EL is positioned, it is possible to effectively prevent dark spots from being generated in the light-emitting layer EL due to an outgas.

The areas R, G, and B in which the light-emitting layer is positioned may be substantially the same as areas in which the sacrificial layer 310 is positioned. When the areas R, G, and B in which the light-emitting layer EL is positioned are the same as the areas in which the sacrificial layer 310 is positioned, since the two layers can be formed using the same mask, a manufacturing process is efficient.

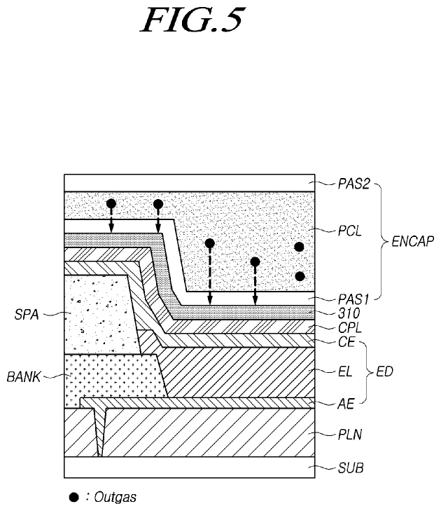

FIG. 5 is a cross-sectional view of a display area of a display device according to embodiments of the present disclosure.

In describing the display device according to embodiments shown in FIG. 5, components which are not specifically described differently may be the same as those of the display device according to embodiments described above with reference to FIG. 3.

Referring to FIG. 5, a sacrificial layer 310 may be positioned in an entire display area as well as an entire area in which a light-emitting layer EL is positioned. When the sacrificial layer 310 is positioned as described above, it is possible to more effectively protect the light-emitting layer EL from an outgas of an organic layer PCL constituting an encapsulation layer ENCAP.

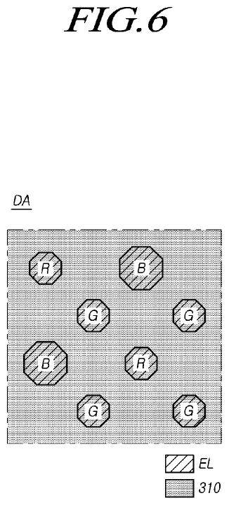

Referring to FIG. 6, a display area DA may include areas R, G, and B in which a light-emitting layer EL is positioned. In addition, a sacrificial layer 310 may be positioned in an entire display area DA. Accordingly, since the sacrificial layer 310 is positioned in an entire area in which the light-emitting layer EL is positioned, it is possible to effectively prevent dark spots from being generated in the light-emitting layer EL due to an outgas.

The above-described embodiments of the present disclosure will be briefly described below.

A display device 100 according to embodiments of the present disclosure may include a substrate SUB, a light-emitting element ED disposed on the substrate SUB, a sacrificial layer 310 positioned on the light-emitting element ED, and an encapsulation layer ENCAP disposed on the sacrificial layer 310.

The light-emitting element ED may include a first compound.

The sacrificial layer 310 may include the first compound.

The encapsulation layer ENCAP may include a second compound.

The first compound may be a dopant compound of a light-emitting layer EL.

The second compound may be a radical derived from a photoinitiator.

A thickness of the sacrificial layer may be 5 to 200 μm.

The first compound has a concentration of 10 mol % or more in the sacrificial layer.

The sacrificial layer 310 may include a third compound, and the third compound may be a reaction product of the first compound and the second compound.

The sacrificial layer may include a third compound represented by any one of Formula 1 and Formula 2 below.

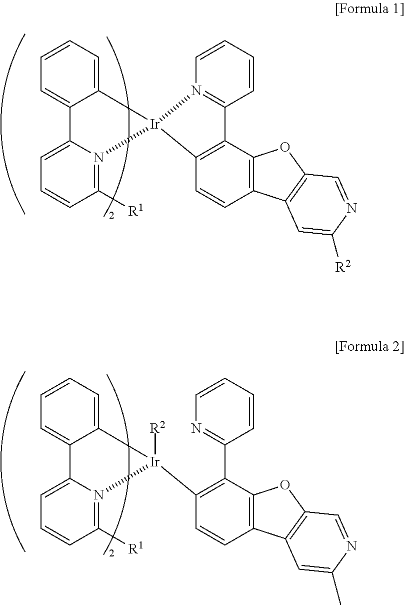

In Formula 1 and Formula 2, R¹ and R² are each independently selected from the group consisting of hydrogen, deuterium, halogen, a C₁-C₂₀ alkyl group, a C₁-C₂₀ haloalkyl group, a C₁-C₂₀ alkoxy group, a C₆-C₂₀ aryl group, —C(═O)R³, —P(═O)(R⁴)(R⁵), and —S(R⁶)(R⁷). At least one of R¹ and R² is not hydrogen and deuterium.

R³ to R⁷ are each independently a C₆-C₂₅ aryl group.

The aryl groups may be each independently substituted with a C₁-C₁₀ alkyl group and S(R⁸), wherein R⁸ is a C₆-C₂₀ aryl group.

The first compound may be one of the following compounds.

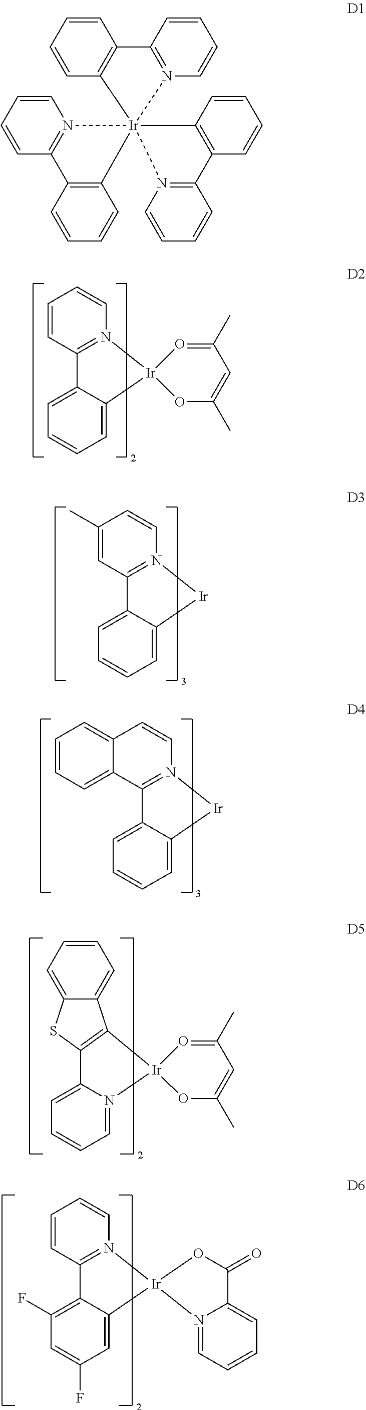

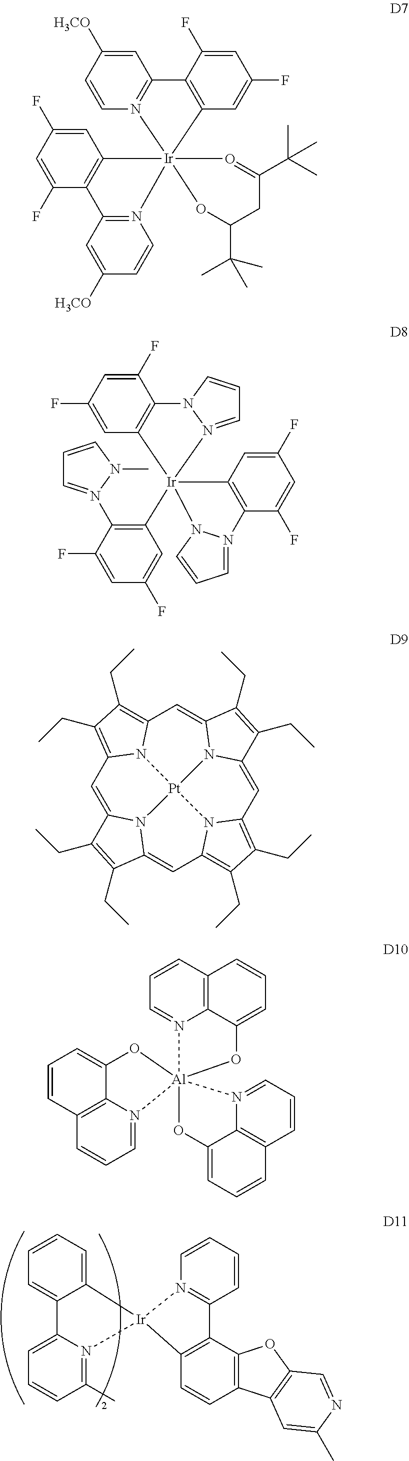

The sacrificial layer 310 may be positioned in an entire area in which the light-emitting layer EL is positioned.

The encapsulation layer ENCAP may include a photocurable resin.

The encapsulation layer ENCAP may include a photoinitiator.

The photoinitiator may be one of the following compounds.

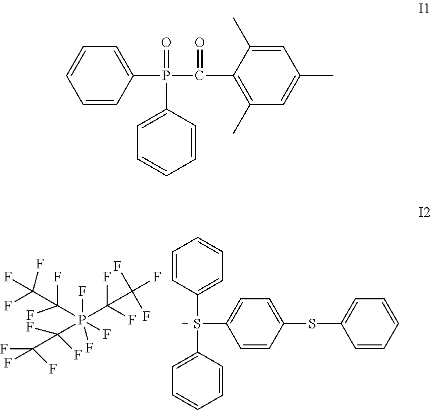

A difference in molecular weight between the third compound and the first compound may be in a range of 19 to 294.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A display device comprising:
a substrate;
a light-emitting element positioned on the substrate and comprising a light-emitting layer including a first compound;
a sacrificial layer disposed on the light-emitting element and comprising the first compound; and
an encapsulation layer positioned on the sacrificial layer and comprising a second compound.

2. The display device of claim 1, wherein the first compound is a dopant compound of the light-emitting layer.

3. The display device of claim 1, wherein the second compound is a radical derived from a photoinitiator.

4. The display device of claim 1, wherein:
the sacrificial layer comprises a third compound; and
the third compound is a reaction product of the first compound and the second compound.

5. The display device of claim 1, wherein the sacrificial layer comprises a third compound represented by any one of Formula 1 and Formula 2 below: 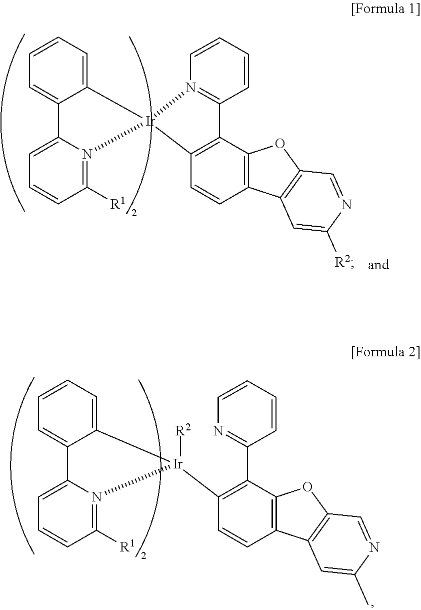
wherein, in Formula 1 and Formula 2, R¹ and R² are each independently selected from the group consisting of hydrogen, deuterium, halogen, a C₁-C₂₀ alkyl group, a C₁-C₂₀ haloalkyl group, a C₁-C₂₀ alkoxy group, a C₆-C₂₀ aryl group, —C(═O)R³, —P(═O)(R⁴)(R⁵), and —S(R⁶)(R⁷), wherein at least one of R¹ and R² is not hydrogen and deuterium,
R³ to R⁷ are each independently a C₆-C₂₅ aryl group, and
the C₆-C₂₅ aryl groups are each independently and optionally substituted with a C₁-C₁₀ alkyl group and S(R⁸), wherein R⁸ is a C₆-C₂₀ aryl group.

6. The display device of claim 1, wherein:
the sacrificial layer comprises a third compound; and
a difference in molecular weight between the third compound and the first compound is in a range of 19 to 294.

7. The display device of claim 1, wherein the first compound is at least one of compounds below:

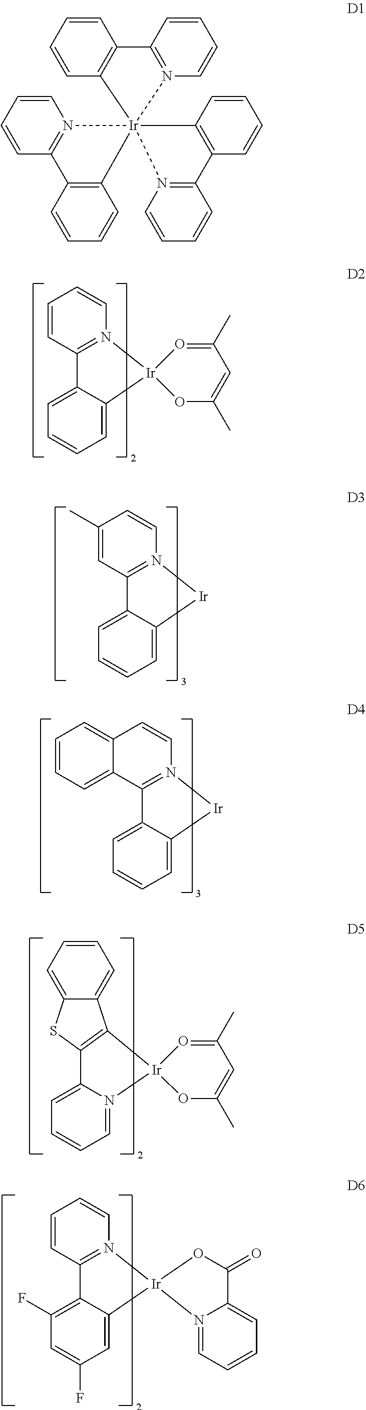

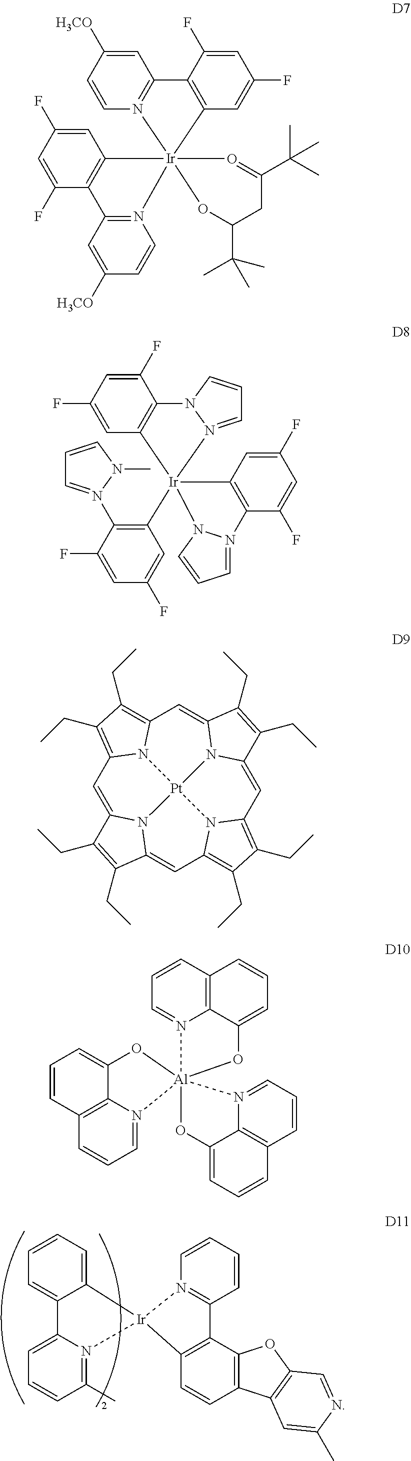

8. The display device of claim 1, wherein the sacrificial layer is positioned in an entire area in which the light-emitting layer is positioned.

9. The display device of claim 1, wherein an area in which the sacrificial layer is positioned is substantially same as an area in which the light-emitting layer is positioned.

10. The display device of claim 9, wherein the sacrificial layer and the light-emitting layer are formed using the same mask.

11. The display device of claim 1, wherein the encapsulation layer comprises a photocurable resin.

12. The display device of claim 1, wherein the encapsulation layer comprises a photoinitiator.

13. The display device of claim 1, wherein the encapsulation layer comprises at least one of compounds below as a photoinitiator: [chemical structure]
